(19) United States
(12) Patent Application Publication
(10) Pub. No.: US 2008/0171409 A1
(43) Pub. Date: Jul. 17, 2008

(54) METHOD FOR FABRICATING BOTTOM-GATE LOW-TEMPERATURE POLYSILICON THIN FILM TRANSISTOR

(76) Inventors: Huang-Chung Cheng, Hsinchu City (TW); Chun-Chien Tsai, Hsinchu City (TW); Hsu-Hsin Chen, Hsinchu City (TW)

Correspondence Address: SINORICA, LLC, 528 FALLSGROVE DRIVE, ROCKVILLE, MD, 20850, US

(21) Appl. No.: 11/935,626

(22) Filed: Nov. 6, 2007

(30) Foreign Application Priority Data
Jan. 12, 2007 (TW) 96101331

(51) Int. Cl. H01L 21/336

(52) U.S. Cl. 438/160; 257/E21.414

(57) ABSTRACT

The present invention discloses a method for fabricating a bottom-gate low-temperature polysilicon thin film transistor, wherein the bottom gate structure is used to form an amorphous silicon layer with varied thicknesses; the amorphous silicon layer in the step region on the border of the bottom gate structure is partially melted by an appropriate amount of laser energy; the partially-melted amorphous silicon layer in the step region functions as crystal seeds and makes crystal grains grow toward the channel region where the amorphous silicon layer is fully melted, and the crystal grains are thus controlled to grow along the lateral direction to form a lateral-grain growth low-temperature polysilicon thin film. The lateral grain growth can reduce the number of the grain boundaries carriers have to pass through. Thus, the present invention can promote the carrier mobility in the active region and the electric performance. Further, the present invention can achieve a superior element motive force and a steeper subthreshold swing.

### BACKGROUND OF THE INVENTION

1. Field of the Invention

The present invention relates to a method for a low-temperature polysilicon thin film transistor, particularly to a method for fabricating a bottom-gate low-temperature polysilicon thin film transistor.

2. Description of the Related Art

Owing to the superior carrier mobility, capability of being formed on a glass substrate, and capability of integrating with a display panel to reduce cost and achieve a high resolution, the low-temperature polysilicon TFT (Thin Film Transistor) has gradually replaced the traditional amorphous silicon TFT and become a critical element in display devices recently.

Refer to FIG. 1 a diagram schematically showing a conventional top-gate low-temperature polysilicon TFT. The conventional top-gate low-temperature polysilicon TFT comprises a substrate 10, a first oxide layer 12 above the substrate 10, a polysilicon channel 14 above the first oxide layer 12, source/drain regions 16 and 16′ above the first oxide layer 12, a top oxide layer 18 above the polysilicon channel 14, and a top gate 20 above the top oxide layer 18. Laser energy is used to promote the crystallinity of the polysilicon. However, a coarse interface and a random grain boundary distribution usually exist between the polysilicon channel 14 and the top oxide layer 18. Besides, too many tiny crystal grains blend with big crystal grains. Thus, the carrier mobility and the electric performance are reduced. Further, in such a conventional transistor structure, the existing polysilicon layer is likely to be damaged by the photolithographic process for fabricating the top oxide layer 18 and the top gate 20.

Accordingly, the present invention proposes a method for fabricating bottom-gate low-temperature polysilicon thin film transistor to control the grain growth of the low-temperature polysilicon layer to overcome the problems mentioned above.

### SUMMARY OF THE INVENTION

The primary objective of the present invention is to provide a method for fabricating a bottom-gate low-temperature polysilicon thin film transistor, whereby polysilicon grains grow laterally in the channel of the active region, and the carriers thus pass through fewer grain boundaries when they cross the active region, and the carrier mobility is thus promoted.

Another objective of the present invention is to provide a method for fabricating a bottom-gate low-temperature polysilicon thin film transistor, whereby polysilicon grains grow laterally in the channel of the active region, and the interface between the active region and the gate insulating layer becomes smoother.

Yet another objective of the present invention is to provide a method for fabricating a bottom-gate low-temperature polysilicon thin film transistor, whereby the transistor has a superior element motive force and a steeper subthreshold swing.

Further another objective of the present invention is to provide a method for fabricating a bottom-gate low-temperature polysilicon thin film transistor, which can fabricate a high-performance transistor simply with a thinner gate oxide layer and can promote the competitiveness of the display products when the transistors fabricated according to the present invention are used as the switch elements of the pixel circuit.

To achieve the abovementioned objectives, the present invention proposes a method for fabricating a bottom-gate low-temperature polysilicon thin film transistor, which comprises the following steps: providing a substrate having an oxide layer and a bottom gate on the surface sequentially; forming a gate insulating layer completely covering the bottom gate and the oxide layer; depositing an amorphous silicon layer on the gate insulating layer, and transforming the amorphous silicon layer into a low-temperature polysilicon layer with laser annealing; implanting ions into the low-temperature polysilicon layer to form source/drain regions; and performing a photolithographic process on the source/drain regions to define the shape of an active region; forming an active region insulating layer over the substrate, and forming several conduction layers connecting to the source/drain regions.

The present invention also proposes another method for fabricating a bottom-gate low-temperature polysilicon thin film transistor, which comprises the following steps: before implanting ions into the low-temperature polysilicon layer to form source/drain regions, forming a photoresist layer over the low-temperature polysilicon layer; performing a backside exposure with the bottom gate being the photomask to obtain a patterned photoresist layer; ion-implanting the low-temperature polysilicon layer with the patterned photoresist layer being the mask to form the source/drain regions; removing the patterned photoresist layer, and fabricating the source/drain regions into the intended shape of the active region with a photolithographic technology; and forming an active region insulating layer and several conduction layers.

To enable the objectives, technical contents, characteristics, and accomplishments of the present invention to be easily understood, the embodiments of the present invention are to be described in detail below.

### BRIEF DESCRIPTION OF THE DRAWINGS

FIG. 1 is a diagram schematically showing the structure of a conventional top-gate low-temperature polysilicon TFT;

FIG. 2(a) to FIG. 2(e) are diagrams schematically showing the steps of fabricating a low-temperature polysilicon layer with a bottom gate according to the present invention;

FIG. 3(a) and FIG. 3(b) are SEM images of the low-temperature polysilicon layers with a single vertical grain boundary according to the present invention;

FIG. 4(a) to FIG. 4(g) are diagrams schematically showing the steps of fabricating a bottom-gate low-temperature polysilicon transistor according to the present invention;

FIG. 5 is a diagram showing the comparison between the electric performances of the bottom-gate low-temperature polysilicon TFT fabricated according to the present invention and the conventional low-temperature polysilicon TFT;

FIG. 6(a) to FIG. 6(g) are diagrams schematically showing the steps of fabricating a bottom-gate low-temperature polysilicon transistor with a self-align technology according to the present invention; and

FIG. 7 is a diagram showing the electric performance comparison between the bottom-gate low-temperature polysilicon transistors fabricated with identical conditions except they are respectively fabricated with a self-align process and a non-self-align process.

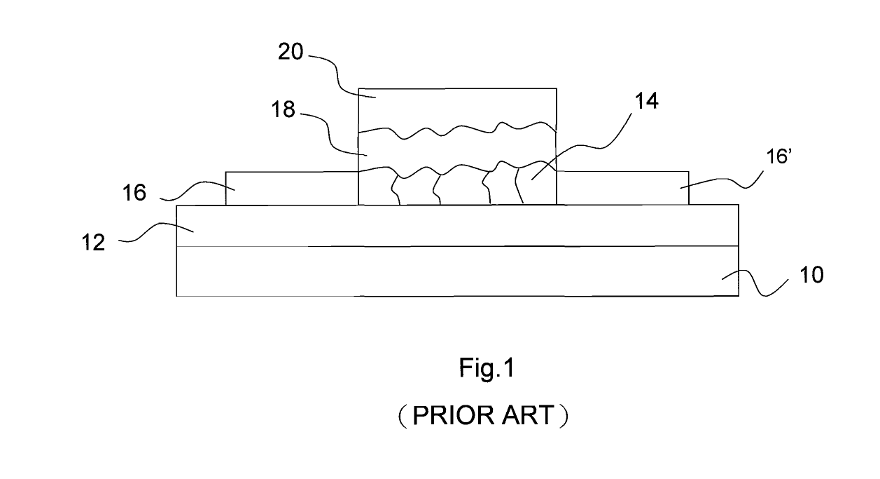

### DETAILED DESCRIPTION OF THE INVENTION

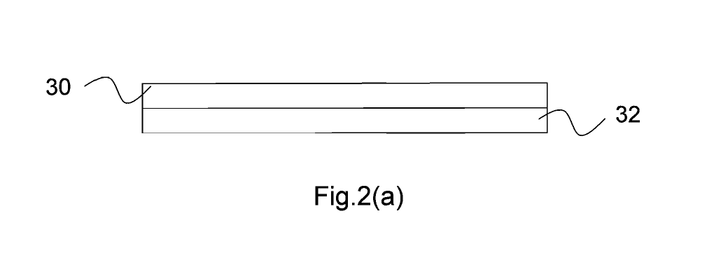

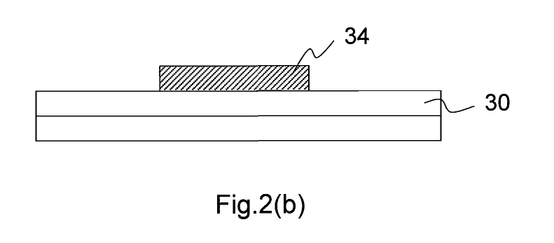

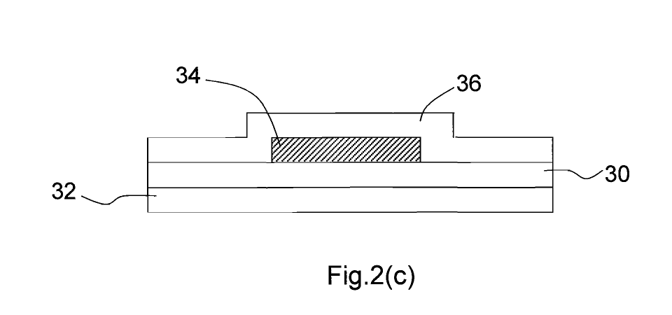

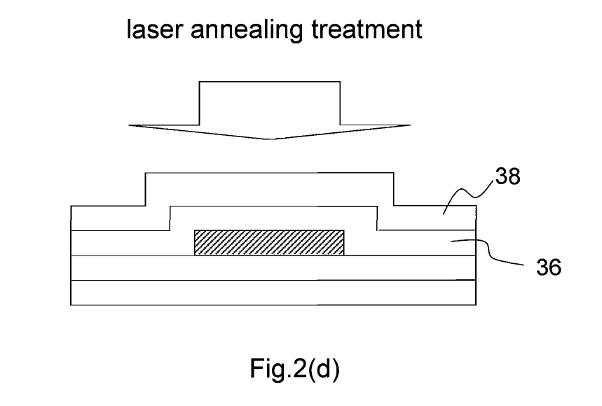

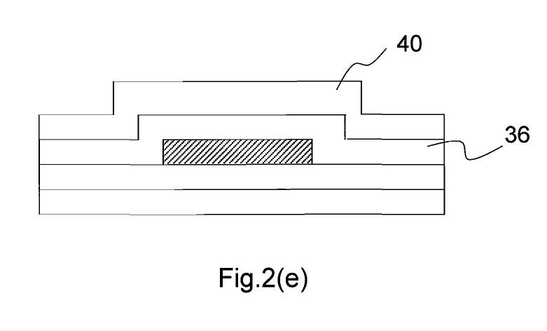

Refer to from FIG. 2(a) to FIG. 2(e) diagrams schematically showing the steps of fabricating a low-temperature polysilicon layer on a substrate with a bottom gate according to the present invention.

As shown in FIG. 2(a), a silicon substrate 32 with an oxide layer 30 is provided; alternatively, the substrate may be made of a glass or plastic. Next, as shown in FIG. 2(b), a gate layer 34 is formed on the oxide layer 30; the gate layer 34 may be a metal layer; alternatively, the gate layer 34 may be obtained via the following steps: decomposing monosilane (SiH4) and hydrogen phosphide (PH3) at 550° C. to form a phosphorus-doped polysilicon layer with a low-temperature CVP (Chemical Vapor Deposition) method, and fabricating the polysilicon layer into the gate layer 34 having the designed pattern with a photolithographic process, wherein the photolithographic process can be implemented with a transformer coupled plasma, and the gate layer 34 has a thickness of between 30 and 500 nm.

Next, as shown in FIG. 2(c), a gate insulating layer 36 is formed over the silicon substrate 32 with a CVD method or a PVD (Physical Vapor Deposition) method, and the gate insulating layer 36 completely covers the gate layer 34 and the oxide layer 30; the gate insulating layer 36 may be an oxide layer, an oxynitride layer, a nitride layer, or a layer made of a high-permittivity material, such as TEOS (tetra ethyl oxysilane); the gate insulating layer 36 has a thickness of between 2 and 300 nm.

Next, as shown in FIG. 2(d), an amorphous silicon layer 38 is formed over the gate insulating layer 36 via a conformal step coverage CVD or PVD method, and the amorphous silicon layer 38 has a thickness of between 10 and 300 nm; a laser is used to anneal and transform the amorphous silicon layer 38 into a low-temperature polysilicon layer 40, wherein the laser may be an excimer laser, a solid-state laser, a pulsed laser, or a continuous wave laser. In the laser annealing process, the substrate is heated to maintain at a temperature of between 20 and 600°C. When a pulsed laser is adopted, the energy density is between 10 mJ/cm² and 2 J/cm². When a continuous wave laser is adopted, the power is within 1 and 500 watts.

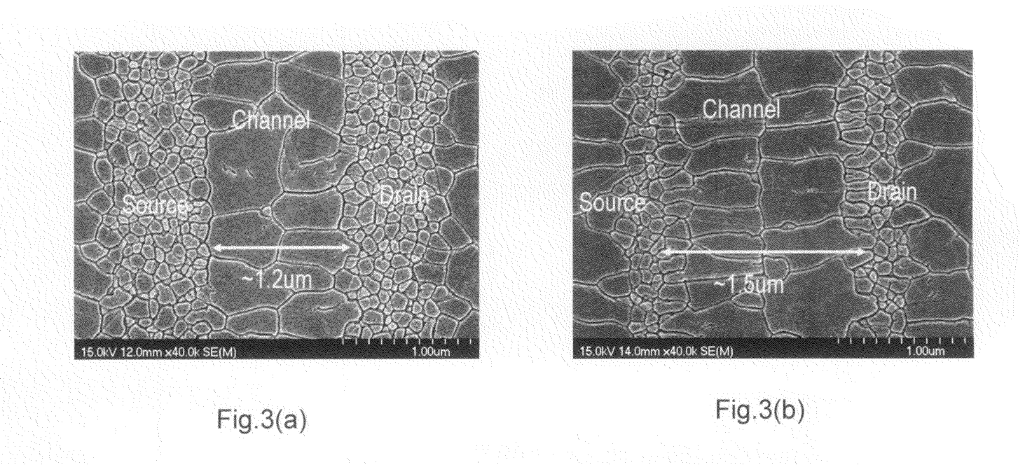

Refer to FIG. 3(a) and FIG. 3(b) SEM (Scanning Electron Microscope) images of the low-temperature polysilicon layers mentioned above, wherein a laser with a energy density of 420 mJ/cm² is adopted to transform amorphous silicon into polysilicon in both two cases, and the bottom gates are the polysilicon gates having a thickness of 1000 Å in both two cases. The low-temperature polysilicon grains shown in FIG. 3(a) have a length of 1.2 μm, and those shown in FIG. 3(b) have a length of 1.5 μm. From the SEM images, it is found that the grains of the low-temperature polysilicon fabricated according to the present invention grow from the seeds of corner region and progress along the opposite direction along the laterally direction, and that a vertical single grain boundary is controlled in the center of the channel region artificially. As the amorphous silicon layer in the channel region is thinner, it will be completely melted after receiving an appropriate amount of laser energy. As the amorphous silicon layer in the step region on the border of the bottom-gate structure is thicker, it is only partially melted after receiving laser energy and leaves behind islands of solid material. The partially-melted amorphous silicon can function as crystal seeds. Therefore, the crystal grains will start to grow from the crystal seeds—the remaining solid-state amorphous silicon and then grow toward the completely melted region until the solid-melt interface from opposite direction impinge to form greater crystal grains in the channel region. Finally, a single vertical grain boundary is formed in the center of the channel region. Further, the channel region is designed to be thinner in the present invention. Therefore, the number of the grain boundaries perpendicular to the carrier current path is effectively reduced, and the field-effect mobility of low-temperature polysilicon is greatly improved. Besides, as the lateral grain growth is driven the bottom-gate structure, the interface between the active region and the gate insulating layer is much smoother that that of the conventional top-gate low-temperature polysilicon transistor.

Below are to be described the embodiments that the abovementioned low-temperature polysilicon layer with a single vertical grain boundary is applied to fabricate transistors.

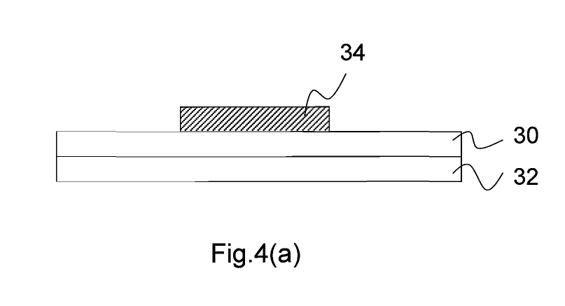

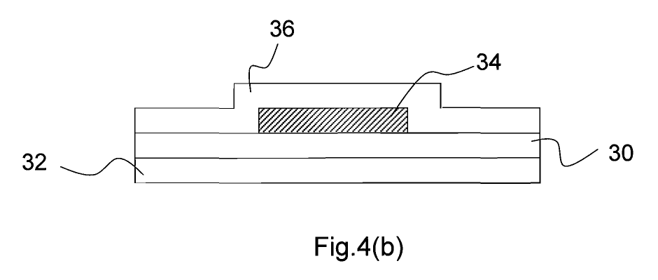

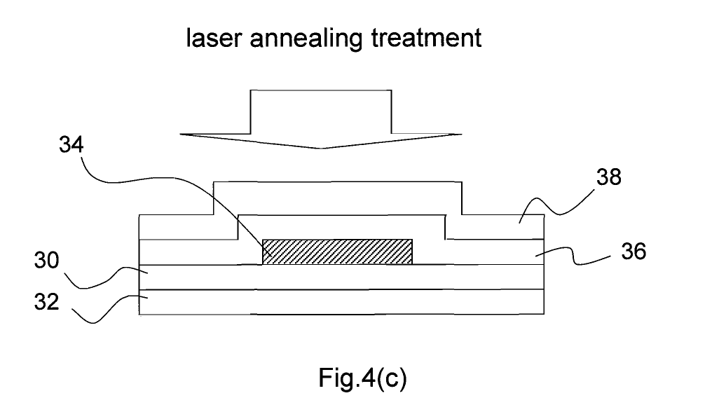

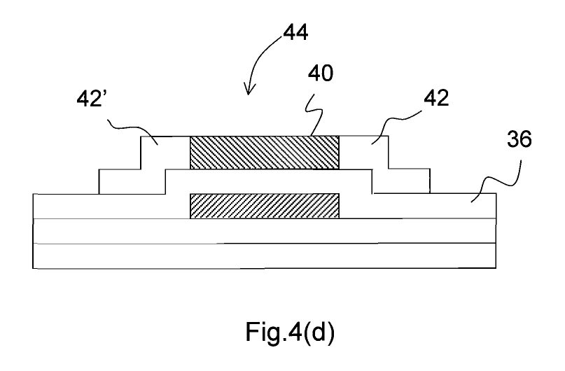

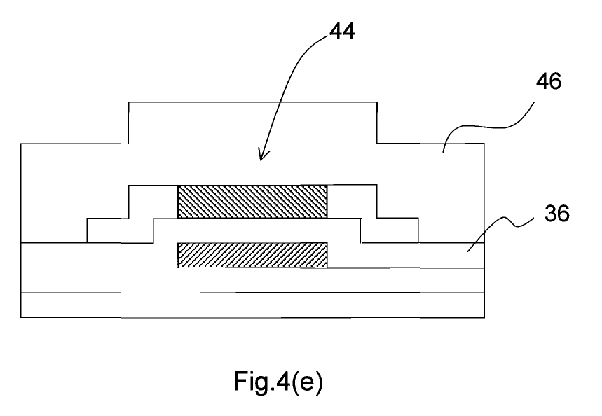

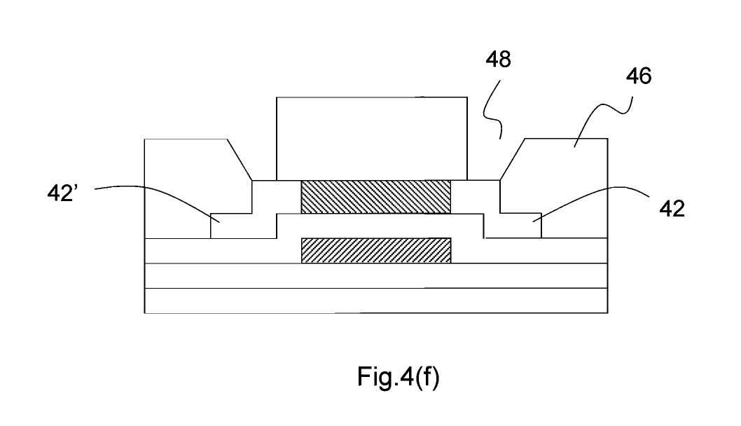

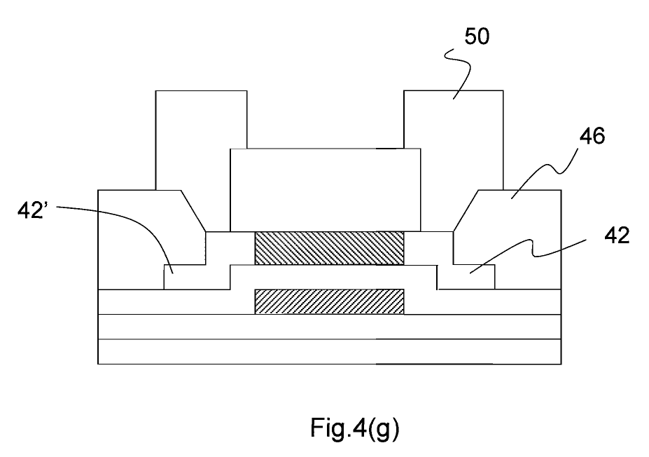

Refer to from FIG. 4(a) to FIG. 4(g) diagrams schematically showing the steps of applying the low-temperature polysilicon layer with a single vertical grain boundary to fabricate transistors. Nevertheless, the detail of the steps, which has been described above, will not repeat herein.

As shown in FIG. 4(a), a silicon substrate 32 with an oxide layer 30 is provided, and a bottom gate layer 34 is formed on the oxide layer 30. Next, as shown in FIG. 4(b), a gate insulating layer 36 is formed over the silicon substrate 32 to completely cover the bottom gate layer 34 and the oxide layer 30.

Next, as shown in FIG. 4(c), an amorphous silicon layer 38 is formed over the gate insulating layer 36 via a conformal step coverage CVD or PVD method, and the amorphous silicon layer 38 has a thickness of between 10 and 300 nm; a KrF excimer laser is used to anneal and transform the amorphous silicon layer 38 into a low-temperature polysilicon layer 40, wherein the pressure is maintained at below 10⁻³ torr, and the substrate is maintained at ambient temperature, and the number of laser shots is 20 (ie. 95% overlapping).

Next, as shown in FIG. 4(d), the low-temperature polysilicon layer is ion-implanted with phosphorous having a dose of 5×10¹⁵ cm⁻² to form the source/drain regions 42 and 42′; then, a transformer coupled plasma is used to etch and pattern the low-temperature polysilicon layer where the source/drain regions have been formed to define the shapes of the source/drain regions 42 and 42′ of the active region 44.

Next, as shown in FIG. 4(e), an active region insulating layer 46 is formed over the silicon substrate 32 with a CVD method or a PVD method to completely cover the active region 44 and the gate insulating layer 36. The active region insulating layer 46 may be an oxide layer, an oxynitride layer, a nitride layer, or a high-permittivity layer. The active region insulating layer 46 has a thickness of between 3000 and 10000 Å. Then, the dopant ions inside the source/drain regions are activated with a laser tempering treatment or with a tempering treatment performed at 600° C. for 12 hours.

Next, as shown in FIG. 4(f), several via-holes 48, which penetrate the active region insulating layer 46 to connect with the source/drain regions 42 and 42′, are formed with a photolithographic technology.

Lastly, as shown in FIG. 4(g), conduction layers 50 are filled into the via-holes 48 to function as conduction lines and then sintered at 400° C. to lower the electric resistance thereof.

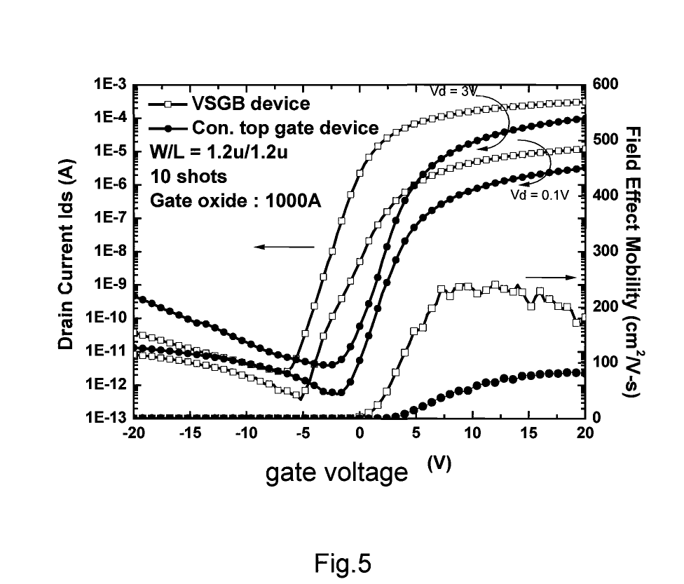

Refer to FIG. 5 a diagram showing the comparison between the electric performances of the bottom-gate low-temperature polysilicon TFT (Thin Film Transistor) fabricated according to the present invention and the conventional low-temperature polysilicon TFT. In both cases, the channel length is 1.2 μm, and the gate thickness is 1000 Å, and the number of the laser shots is 10 (i.e. 90% overlapping). From FIG. 5, it is found that the field effect mobility of the transistor fabricated according to the present invention can reach as high as 250 cm²/V-s, and that the field effect mobility of the conventional top-gate low-temperature polysilicon TFT can only reach 79 cm²/V-s. Therefore, the electric performance of the transistor fabricated according to the present invention is obviously superior to that of the conventional top-gate low-temperature polysilicon TFT. In the transistor fabricated according to the present invention, the drain leakage and kink effect induced by the gate are reduced, and the uniformity of elements is greatly promoted. Therefore, without any special structure or material, the bottom-gate low-temperature polysilicon TFT fabricated according to the present invention can simply utilize a thinner gate oxide layer to achieve a superior element motive force and a steeper subthreshold swing.

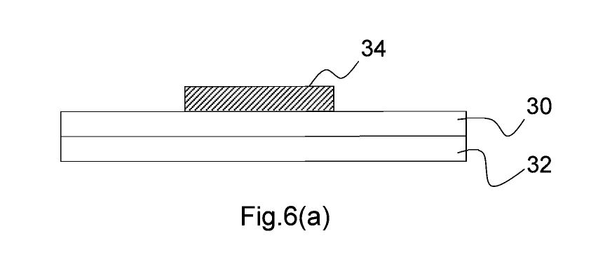

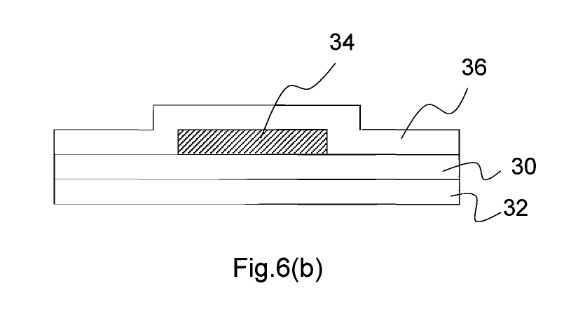

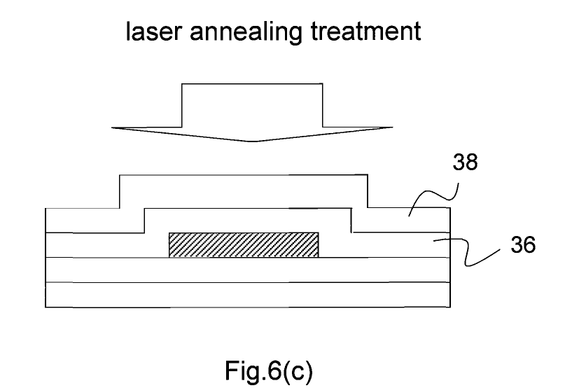

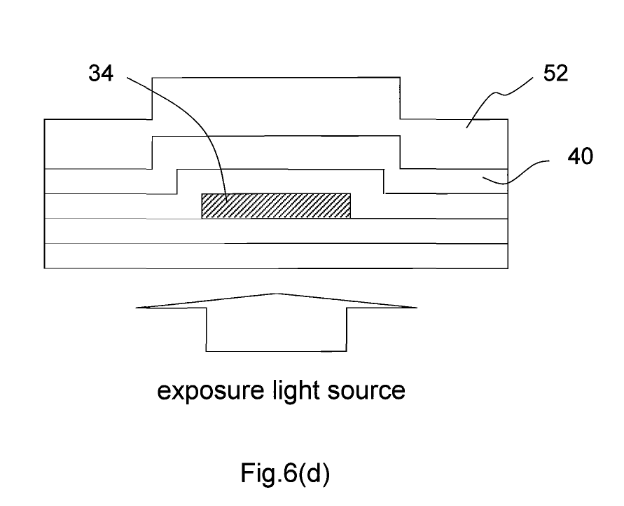

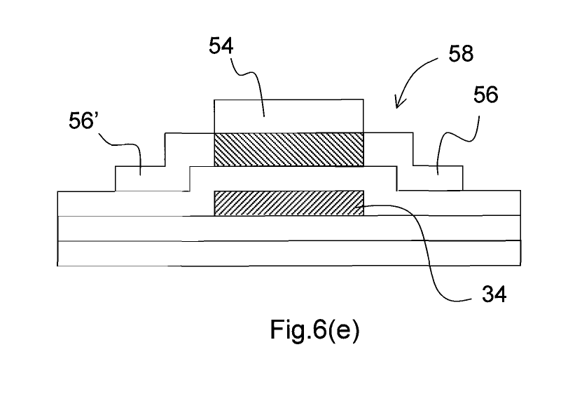

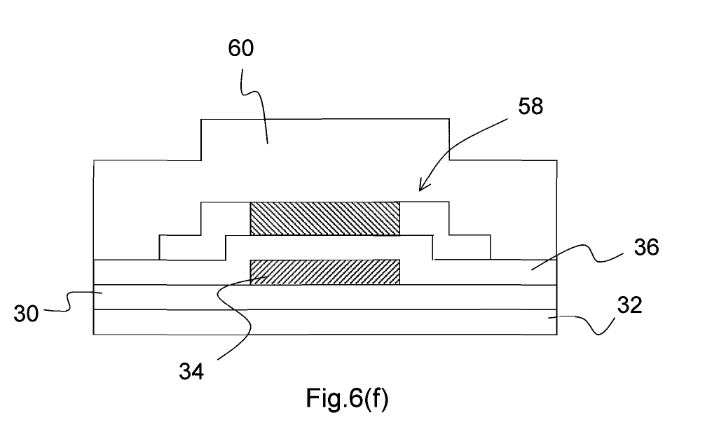

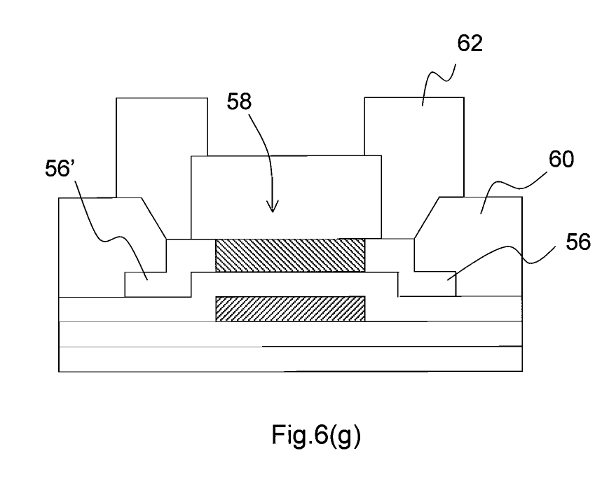

Refer to from FIG. 6(a) to FIG. 6(g). The present invention also proposes another method for fabricating a bottom-gate low-temperature polysilicon thin film transistor, wherein the low-temperature polysilicon layer with a single vertical grain boundary is applied to fabricate transistors, and a self-align process is used to overcome the asymmetry or deviation of the ion implantation for the source/drain regions. Nevertheless, the detail of the steps, which has been described above, will not repeat herein.

As shown in FIG. 6(a), a silicon substrate 32 is provided with an oxide layer 30 and a bottom gate layer 34 sequentially formed on the surface thereof. Next, as shown in FIG. 6(b), a gate insulating layer 36 is formed over the silicon substrate 32 to completely cover the bottom gate layer 34 and the oxide layer 30.

Next, as shown in FIG. 6(c), an amorphous silicon layer 38 is formed over the gate insulating layer 36 via a conformal step coverage deposition method, and the amorphous silicon layer 38 has a thickness of between 10 and 300 nm; a laser is used to anneal and transform the amorphous silicon layer 38 into a low-temperature polysilicon layer 40, wherein the laser may be an excimer laser, a solid-state laser, a pulsed laser, or a continuous wave laser.

Then, a self-align process is undertaken. As shown in FIG. 6(d), a photoresist layer 52 is formed over the low-temperature polysilicon layer 40; a backside exposure is performed on the photoresist layer 52 with the bottom gate layer 34 being the photomask to obtain a patterned photoresist layer 54 and define the source/drain regions, wherein the light source of the backside exposure has a wavelength of below 450 nm, and the energy density of exposure is between 1 mJ/cm² and 1 J/cm², and the exposure time is between 0.1 and 1000 sec.

Next, as shown in FIG. 6(e), the low-temperature polysilicon layer 40 is ion-implanted with the patterned photoresist layer 54 being the mask to form source/drain regions 56 and 56′, and the self-align process is thus completed. Then, a photolithographic technology is used to pattern the source/drain regions 56 and 56′ and define an active region 58.

Next, as shown in FIG. 6(f), the patterned photoresist layer 54 is removed, and an active region insulating layer 60 is formed to completely cover the active region 58 and the gate insulating layer 36. Then, the dopant ions inside the source/drain regions 56 and 56′ are activated with a laser tempering treatment or with a tempering treatment performed at 600° C. for 12 hours.

Lastly, as shown in FIG. 6(g), several via-holes, which penetrate the active region insulating layer 60 to connect with the source/drain regions 56 and 56′, are formed with a photolithographic technology; conduction layers 62 are filled into the via-holes to function as conduction lines and then sintered at 400° C. to lower the electric resistance thereof. Thus is completed a bottom-gate low-temperature polysilicon TFT.

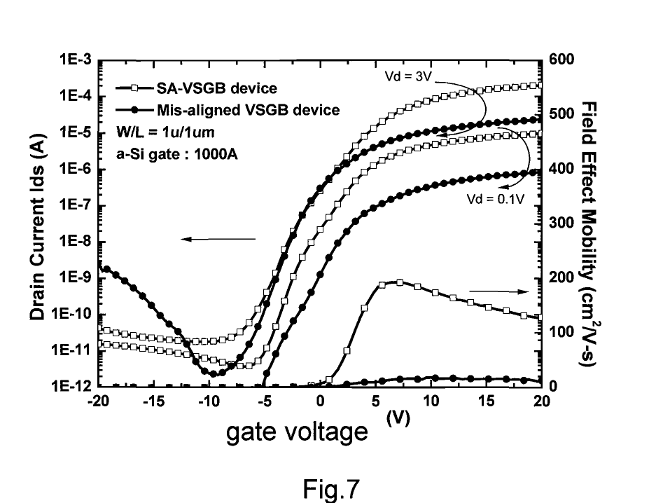

Refer to FIG. 7 a diagram showing the electric performance comparison between the transistors fabricated with identical conditions except they are respectively fabricated with a self-align process and a non-self-align process. In both cases, the gate thickness s 1000 Å, and the channel length is 1 μm, and the number of laser shots is 20. From FIG. 7, it is found that the carrier mobility of the transistor fabricated with a self-align process can reach about 192 cm²/V-s, and that the carrier mobility of the transistor fabricated with a non-self-align process is only about 17.76 cm²/V-s. Further, the patterned photoresist layer can perfectly align the exposure to the intended source/drain regions. Thus, in addition to having the characteristics of the abovementioned low-temperature polysilicon transistor with a single vertical grain boundary, the transistor fabricated with a self-align process also has good electric performance symmetry. Then, the conventional drain leakage and kink effect induced by the gate are reduced. Therefore, the low-temperature polysilicon transistor having a single vertical grain boundary fabricated with a self-align process according to the present invention can apply to the switch elements of the pixel circuit to promote the response speed of display devices.

In summary, the present invention utilizes the bottom gate structure to form an amorphous silicon layer with varied thicknesses. An appropriate amount of laser energy is used to divide the amorphous silicon layer into a partially-melted step region on the border of the bottom gate structure and a full-melted channel region. The partially-melted region functions as crystal seeds and makes the crystal grains grow laterally from the seeds of corner region and progress along the opposite direction and vertical single grain boundary thus finally appears in the center of the channel. Thereby, the field-effect mobility of polysilicon is greatly improved. In the present invention, as the crystal grains grow along the lateral direction in the channel region, the interface between the active region and the gate insulating layer is much smoother that that of the conventional top-gate low-temperature polysilicon transistor. Thus, the transistor fabricated according to the present invention has a superior element motive force and a steeper subthreshold swing. Further, the present invention may use the bottom gate as the photomask of a backside exposure to fabricate a self-align bottom-gate low-temperature polysilicon TFT, which has good electric performance symmetry of the source/drain regions and can apply to the switch elements of the pixel circuit to promote the response speed of display devices.

Those described above are the preferred embodiments to exemplify the present invention. However, it is not intended to limit the scope of the present invention. Any equivalent modification or variation according to the spirit of the present invention is to be also included within the scope the claims of the present invention.

What is claimed is:

1. A method for fabricating a bottom-gate low-temperature polysilicon thin film transistor, comprising the following steps:
providing a substrate sequentially having an oxide layer and a bottom gate on surface thereof;
forming a gate insulating layer over said substrate with said gate insulating layer completely covering said bottom gate and said oxide layer;
depositing an amorphous silicon layer on said gate insulating layer;
transforming said amorphous silicon layer into a low-temperature polysilicon layer with a laser annealing process;
implanting ions into said low-temperature polysilicon layer to form source/drain regions;
performing a photolithographic process on said source/drain regions to define shape of an active region; and
forming an active region insulating layer over said substrate, and forming several conduction layers, which penetrate said active region insulating layer to connect with said source/drain regions.

2. The method for fabricating a bottom-gate low-temperature polysilicon thin film transistor according to claim 1, wherein said substrate is a glass or plastic substrate.

3. The method for fabricating a bottom-gate low-temperature polysilicon thin film transistor according to claim 1, wherein said bottom gate is a metal layer or a doped polysilicon layer and has a thickness of between 30 and 500 nm.

4. The method for fabricating a bottom-gate low-temperature polysilicon thin film transistor according to claim 1, wherein said gate insulating layer is formed with a chemical vapor deposition method or a physical vapor deposition method, and said gate insulating layer is an oxide layer, an oxynitride layer, a nitride layer or a high-permittivity layer.

5. The method for fabricating a bottom-gate low-temperature polysilicon thin film transistor according to claim 1, wherein said gate insulating layer has a thickness of between 2 and 300 nm.

6. The method for fabricating a bottom-gate low-temperature polysilicon thin film transistor according to claim 1, wherein said amorphous silicon layer is formed via a conformal step coverage chemical vapor deposition method or via a conformal step coverage physical vapor deposition method.

7. The method for fabricating a bottom-gate low-temperature polysilicon thin film transistor according to claim 1, wherein said amorphous silicon layer has a thickness of between 10 and 300 nm.

8. The method for fabricating a bottom-gate low-temperature polysilicon thin film transistor according to claim 6, wherein said amorphous silicon layer has a thickness of between 10 and 300 nm.

9. The method for fabricating a bottom-gate low-temperature polysilicon thin film transistor according to claim 1, wherein said laser annealing process adopts an excimer laser, a solid-state laser, a pulsed laser, or a continuous wave laser as laser source.

10. The method for fabricating a bottom-gate low-temperature polysilicon thin film transistor according to claim 9, wherein said pulsed laser has an energy density of between 10 mJ/cm² and 2 J/cm², and said continuous wave laser has an energy density of between 1 and 500 watt.

11. The method for fabricating a bottom-gate low-temperature polysilicon thin film transistor according to claim 1, wherein said substrate is heated to a temperature of between 20 and 600° C. in said laser annealing process.

12. A method for fabricating a bottom-gate low-temperature polysilicon thin film transistor, comprising the following steps:
providing a substrate sequentially having an oxide layer and a bottom gate on surface thereof;
forming a gate insulating layer over said substrate with said gate insulating layer completely covering said bottom gate and said oxide layer;
depositing an amorphous silicon layer on said gate insulating layer;
transforming said amorphous silicon layer into a low-temperature polysilicon layer with a laser annealing process;
forming a photoresist layer on said low-temperature polysilicon layer;
performing a backside exposure on said photoresist layer with said bottom gate being photomask to obtain a patterned photoresist layer;
implanting ions into said low-temperature polysilicon layer with said patterned photoresist layer being mask to form source/drain regions;
removing said patterned photoresist layer;
performing a photolithographic process on said source/drain regions to define shape of an active region;
forming an active region insulating layer over said substrate, and forming several conduction layers, which penetrate said active region insulating layer to connect with said source/drain regions.

13. The method for fabricating a bottom-gate low-temperature polysilicon thin film transistor according to claim 12, wherein said substrate is a glass or plastic substrate.

14. The method for fabricating a bottom-gate low-temperature polysilicon thin film transistor according to claim 12, wherein said bottom gate is a metal layer or a doped polysilicon layer.

15. The method for fabricating a bottom-gate low-temperature polysilicon thin film transistor according to claim 12, wherein said bottom gate has a thickness of between 30 and 500 nm.

16. The method for fabricating a bottom-gate low-temperature polysilicon thin film transistor according to claim 12, wherein said gate insulating layer is formed with a chemical vapor deposition method or a physical vapor deposition method, and said gate insulating layer is an oxide layer, an oxynitride layer, a nitride layer or a high-permittivity layer.

17. The method for fabricating a bottom-gate low-temperature polysilicon thin film transistor according to claim 12, wherein said gate insulating layer has a thickness of between 2 and 300 nm.

18. The method for fabricating a bottom-gate low-temperature polysilicon thin film transistor according to claim 12, wherein said amorphous silicon layer is formed via a conformal step coverage chemical vapor deposition method or via a conformal step coverage physical vapor deposition method.

19. The method for fabricating a bottom-gate low-temperature polysilicon thin film transistor according to claim 12, wherein said amorphous silicon layer has a thickness of between 10 and 300 nm.

20. The method for fabricating a bottom-gate low-temperature polysilicon thin film transistor according to claim 12, wherein said laser annealing process adopts an excimer laser, a solid-state laser, a pulsed laser, or a continuous wave laser as laser source.

21. The method for fabricating a bottom-gate low-temperature polysilicon thin film transistor according to claim 12, wherein said pulsed laser has an energy density of between 10 mJ/cm² and 2 J/cm², and said continuous wave laser has an energy density of between 1 and 500 watt.

22. The method for fabricating a bottom-gate low-temperature polysilicon thin film transistor according to claim 12, wherein said substrate is heated to a temperature of between 20 and 600° C. in said laser annealing process.

23. The method for fabricating a bottom-gate low-temperature polysilicon thin film transistor according to claim 12, wherein light source of said backside exposure has a wavelength of below 450 nm.

24. The method for fabricating a bottom-gate low-temperature polysilicon thin film transistor according to claim 12, wherein exposure energy density of said backside exposure is between 1 mJ/cm² and 1 J/cm², and exposure time of said backside exposure is between 0.1 and 1000 sec.

25. The method for fabricating a bottom-gate low-temperature polysilicon thin film transistor according to claim 24, wherein the exposure energy density of said backside exposure is between 1 mJ/cm² and 1 J/cm², and the exposure time of said backside exposure is between 0.1 and 1000 sec.
